(19) United States
(12) Patent Application Publication
(10) Pub. No.: US 2024/0268238 A1
(43) Pub. Date: Aug. 8, 2024

(54) MAGNETIC MEMORY DEVICE

(71) Applicants: Kioxia Corporation, Tokyo (JP); SK hynix Inc., Icheon-si (KR)

(72) Inventors: Tadaaki OIKAWA, Seoul (KR); Hyung-Woo AHN, Seongnam-si (KR); Taiga ISODA, Tokyo (JP); Kenji FUKUDA, Seoul (KR); Junghyeok KWAK, Icheon-si (KR)

(73) Assignees: Kioxia Corporation, Tokyo (JP); SK hynix Inc., Icheon-si (KR)

(21) Appl. No.: 18/402,900

(22) Filed: Jan. 3, 2024

(30) Foreign Application Priority Data
Feb. 8, 2023 (JP) 2023-017856

(51) Int. Cl. H10N 50/20; H10B 61/00; H10N 50/85

(52) U.S. Cl. CPC H10N 50/20; H10B 61/10; H10N 50/85

(57) ABSTRACT

According to one embodiment, a magnetic memory device includes a first ferromagnetic layer, a first nonmagnetic layer provided on the first ferromagnetic layer, a second ferromagnetic layer provided on the first nonmagnetic layer, an oxide layer containing magnesium (Mg), a rare-earth element, and a noble-metal element and provided on the second ferromagnetic layer, and a second nonmagnetic layer provided on the oxide layer.

### CROSS-REFERENCE TO RELATED APPLICATIONS

This application is based upon and claims the benefit of priority from Japanese Patent Application No. 2023-017856, filed Feb. 8, 2023, the entire contents of which are incorporated herein by reference.

### FIELD

Embodiments described herein relate generally to a magnetic memory device.

### BACKGROUND

A magnetoresistive random access memory (MRAM) that uses a magnetoresistive effect element as a memory element is known.

### BRIEF DESCRIPTION OF THE DRAWINGS

FIG. 1 is a block diagram showing an example of a configuration of a memory system including a magnetic memory device according to an embodiment.

FIG. 2 is a circuit diagram showing an example of a circuit configuration of a memory cell array included in the magnetic memory device according to the embodiment.

FIG. 3 is a perspective view showing an example of a structure of the memory cell array included in the magnetic memory device according to the embodiment.

FIG. 4 is a cross-sectional diagram showing an example of a cross-sectional structure of a variable resistance element included in the memory cell of the magnetic memory device according to the embodiment.

FIG. 5 is a schematic diagram showing an example of a change in characteristics based on a difference in an SL capping layer and a top layer of the variable resistance element.

### DETAILED DESCRIPTION

In general, according to one embodiment, a magnetic memory device includes a first ferromagnetic layer, a first nonmagnetic layer provided on the first ferromagnetic layer, a second ferromagnetic layer provided on the first nonmagnetic layer, an oxide layer containing magnesium (Mg), a rare-earth element, and a noble-metal element and provided on the second ferromagnetic layer, and a second nonmagnetic layer provided on the oxide layer.

An embodiment will be described below with reference to the accompanying drawings. The drawings are either schematic or conceptual. The dimensions, ratios, etc. in the drawings are not always the same as the actual ones. In the descriptions below, constituent elements having approximately the same function and configuration will be denoted by the same reference symbol. A numeral, etc., following letters constituting a reference symbol is used to distinguish between elements referred to by reference symbols including the same letters and having the same configuration. If elements represented by reference symbols that include the same letters need not be distinguished from one another, they are referred to by reference symbols that include only letters.

### 1. Configuration

Hereinafter, a memory system MS according to an embodiment will be described.

### 1.1. Configuration of Memory System

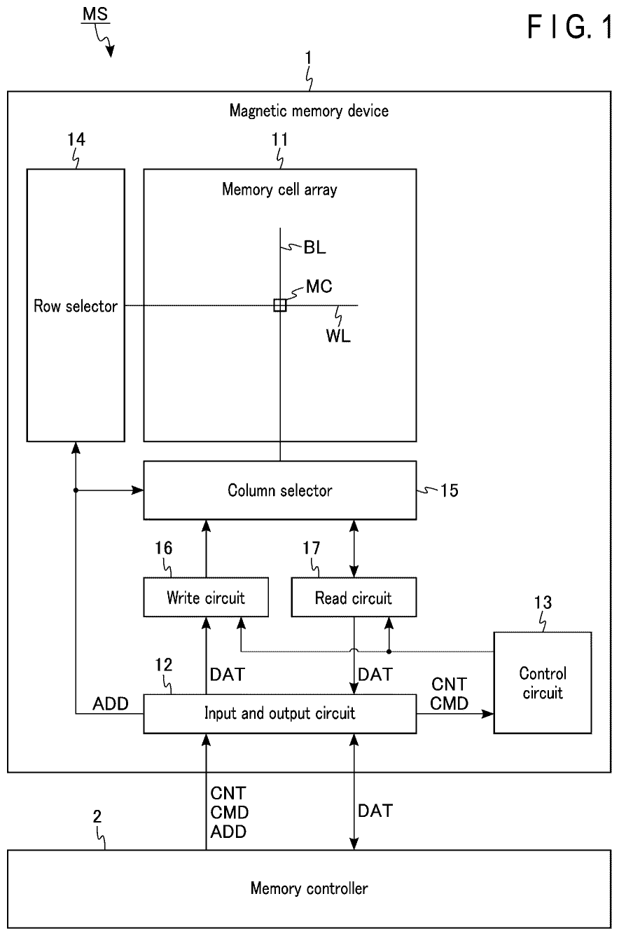

First, an example of a configuration of a memory system MS will be described with reference to FIG. 1. FIG. 1 is a block diagram showing a configuration example of the memory system MS according to the embodiment.

As shown in FIG. 1, the memory system MS includes a magnetic memory device 1 and a memory controller 2. The magnetic memory device 1 operates based on control of the memory controller 2. The memory controller 2 may order the magnetic memory device 1 to perform a read operation, a write operation, etc., in response to a request (order) from an external host device.

The magnetic memory device 1 is a memory device in which magnetic tunnel junction (MTJ) elements are used as memory cells, and is a type of variable resistance memory. The MTJ elements use a magnetoresistance effect caused by a magnetic tunnel junction. The MTJ elements are also referred to as “magnetoresistance effect elements”. The magnetic memory device 1 includes, for example, a memory cell array 11, an input and output circuit 12, a control circuit 13, a row selector 14, a column selector 15, a write circuit 16, and a read circuit 17.

The memory cell array 11 includes a plurality of memory cells MC, a plurality of word lines WL, and a plurality of bit lines BL. FIG. 1 shows a set of a memory cell MC, a word line WL, and a bit line BL. The memory cell MC can store data in a non-volatile manner. The memory cell MC is coupled between a single word line WL and a single bit line BL, and is associated with a set of a row and a column. A row address is assigned to the word line WL. A column address is assigned to the bit line BL. One or more memory cells MC may be specified by selection of one row and selection of one or more columns.

The input and output circuit 12 is coupled to the memory controller 2, and controls communications between the magnetic memory device 1 and the memory controller 2. The input and output circuit 12 transfers a control signal CNT and a command CMD received from the memory controller 2 to the control circuit 13. The input and output circuit 12 transfers a row address and a column address included in an address signal ADD received from the memory controller 2 to the row selector 14 and the column selector 15, respectively. The input and output circuit 12 transfers data DAT (write data) received from the memory controller 2 to the write circuit 16. The input and output circuit 12 transfers data DAT (read data) received from the read circuit 17 to the memory controller 2.

The control circuit 13 controls the operation of the entire magnetic memory device 1. The control circuit 13 executes a read operation, a write operation, etc. based on, for example, control instructed by the control signal CNT and the command CMD. The control circuit 13 supplies, for example, a voltage to be used in data writing in the write operation to the write circuit 16. Also, the control circuit 13 supplies a voltage to be used in data reading in the read operation to the read circuit 17.

The row selector 14 is coupled to a plurality of word lines WL. The row selector 14 selects a single word line WL specified by a row address. The selected word line WL is, for example, electrically coupled to a driver circuit (not illustrated).

The column selector 15 is coupled to a plurality of bit lines BL. The column selector 15 selects one or more bit lines BL specified by a column address. The selected bit line BL is, for example, electrically coupled to a driver circuit (not illustrated).

The write circuit 16 supplies a voltage to be used in data writing to the column selector 15 based on the control of the control circuit 13 and the data DAT (write data) received from the input and output circuit 12. Upon flowing of a current based on the write data through a memory cell MC, desired data is written into the memory cell MC.

The read circuit 17 includes a sense amplifier. The read circuit 17 supplies a voltage to be used in data reading to the column selector 15 based on the control of the control circuit 13. The sense amplifier determines data stored in the memory cell MC based on a voltage or a current of the selected bit line BL. Thereafter, the read circuit 17 transfers data DAT (read data) corresponding to a determination result to the input and output circuit 12.

### 1.2. Circuit Configuration of Memory Cell Array

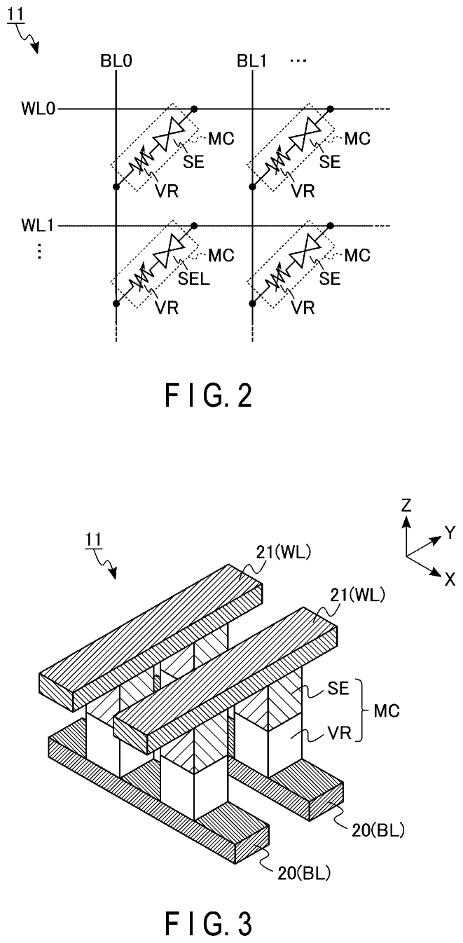

Next, an example of a circuit configuration of the memory cell array 11 will be described with reference to FIG. 2. FIG. 2 is a circuit diagram showing an example of a circuit configuration of the memory cell array 11 of the magnetic memory device 1 according to the embodiment. Of a plurality of word lines WL and a plurality of bit lines BL, word lines WL0 and WL1 and bit lines BL0 and BL1 are extracted in FIG. 2.

As shown in FIG. 2, a single memory cell MC is coupled between each of WL0 and BL0, WL0 and BL1, WL1 and BL0, and WL1 and BL1. In the memory cell array 11, a plurality of memory cells MC are arranged in a matrix, for example.

Each memory cell MC includes a variable resistance element VR and a switching element SE. The variable resistance element VR and the switching element SE are coupled in series between a bit line BL and a word line WL associated therewith. For example, one end of the variable resistance element VR is coupled to the bit line BL. The other end of the variable resistance element VR is coupled to one end of the switching element SE. The other end of the switching element SE is coupled to the word line WL. A coupling relationship between the variable resistance element VR and the switching element SE between the bit line BL and the word line WL may be reversed.

The variable resistance element VR corresponds to an MTJ element. The variable resistance element VR may store data in a nonvolatile manner based on its resistance value. For example, a memory cell MC including a variable resistance element VR in a high-resistance state stores “1” data. A memory cell MC including a variable resistance element VR in a low-resistance state stores “0” data. Allocation of data associated with the resistance value of the variable resistance element VR may be set differently. The resistance state of the variable resistance element VR may vary depending on the current flowing through the variable resistance element VR.

The switching element SE is, for example, a bidirectional diode. The switching element SE functions as a selector which controls supply of a current to the associated variable resistance element VR. Specifically, a switching element SE included in a memory cell MC is turned off if a voltage applied to the memory cell MC is below a threshold voltage of the switching element SE, and is turned on if the voltage applied to the memory cell MC is equal to or greater than the threshold voltage of the switching element SE. A switching element SE in an off state functions as an insulator having a high resistance value. With the switching element SE in an off state, a current flow between a word line WL and a bit line BL coupled to the memory cell MC is suppressed. A switching element SE in an on state functions as a conductor having a low resistance value. With the switching element SE in an on state, a current flows between a word line WL and a bit line BL coupled to the memory cell MC. Namely, the switching element SE is capable of switching between whether or not to let a current flow according to the magnitude of the voltage applied to the memory cell MC, regardless of the direction of the current flow. As the switching element SE, other elements such as a transistor may be used.

### 1.3. Structure of Memory Cell Array

An example of a structure of the memory cell array 11 according to the embodiment will be described below. In the following description, an xyz orthogonal coordinate system will be used. An X direction corresponds to a direction in which the bit lines BL extend. A Y direction corresponds to a direction in which the word lines WL extend. A Z direction corresponds to a direction vertical to a surface of a semiconductor substrate used for forming the magnetic memory device 1. The term “low” and its derivatives and relevant terms refer to a position with a smaller coordinate on the z axis. The term “up” and its derivatives and relevant terms refer to a position with a larger coordinate on the z axis. In the perspective views, hatching is applied, where necessary. The hatching applied in the perspective views does not necessarily relate to the material or characteristics of the hatched components. In the perspective views and the cross-sectional views, illustration of the components such as an interlayer insulating film is omitted.

### 1.3.1. Three-dimensional Structure of Memory Cell Array

Next, an example of a three-dimensional structure of a memory cell array will be described with reference to FIG. 3. FIG. 3 is a perspective view showing an example of a structure of the memory cell array 11 included in the magnetic memory device 1 according to the embodiment.

As shown in FIG. 3, the memory cell array 11 includes a plurality of conductive layers 20 and a plurality of conductive layers 21.

Each of the conductive layers 20 includes a portion extending in the X direction. The conductive layers 20 are arranged in the Y direction and spaced apart from each other. Each conductive layer 20 is used as a bit line BL.

Each of the conductive layers 21 includes a portion extending in the Y direction. The conductive layers 21 are arranged in the X direction so as to be distanced from each other. Each conductive layer 21 is used as a word line WL.

An interconnect layer in which the conductive layers 21 are provided is arranged above an interconnect layer in which the conductive layers 20 are provided. A single memory cell MC is provided at each portion where the conductive layers 20 and the conductive layers 21 cross each other. In other words, each memory cell MC is provided in a columnar shape between a bit line BL and a word line WL associated therewith. In this example, the variable resistance element VR is provided on the conductive layer 20. A switching element SE is provided on the variable resistance element VR. The conductive layer 21 is provided on the switching element SE.

A case has been described where the variable resistance element VR is provided below the switching element SE; however, the variable resistance element VR may be provided above the switching element SE, depending on the circuit configuration of the memory cell array 11.

### 1.3.2. Cross-sectional Structure of Variable Resistance Element

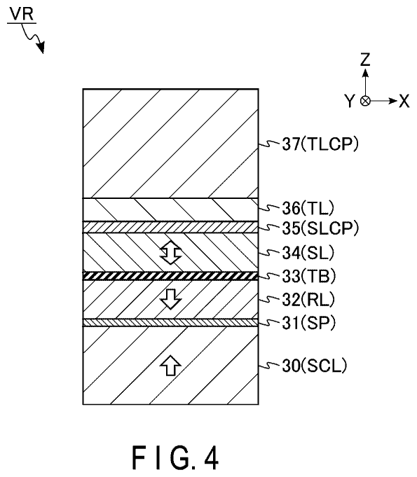

Next, a cross-sectional structure of the variable resistance element will be described with reference to FIG. 4. FIG. 4 is a cross-sectional diagram showing an example of a cross-sectional structure of the variable resistance element VR included in the memory cell MC of the magnetic memory device 1 according to the embodiment.

As shown in FIG. 4, a variable resistance element VR includes, for example, a ferromagnetic layer 30, a nonmagnetic layer 31, a ferromagnetic layer 32, a nonmagnetic layer 33, a ferromagnetic layer 34, an oxide layer 35, and nonmagnetic layers 36 and 37. In FIG. 4, magnetization directions of magnetic layers are indicated by arrows. A bidirectional arrow indicates that the magnetization direction is variable.

The ferromagnetic layer 30, the nonmagnetic layer 31, the ferromagnetic layer 32, the nonmagnetic layer 33, the ferromagnetic layer 34, the oxide layer 35, and the nonmagnetic layers 36 and 37 are stacked in this order from the side of the conductive layer 20 (bit line BL) toward the side of the conductive layer 21 (word line WL). Specifically, the ferromagnetic layer 30 is provided above the conductive layer 20. The nonmagnetic layer 31 is provided on the ferromagnetic layer 30. The ferromagnetic layer 32 is provided on the nonmagnetic layer 31. The nonmagnetic layer 33 is provided on the ferromagnetic layer 32. The ferromagnetic layer 34 is provided on the nonmagnetic layer 33. The oxide layer 35 is provided on the ferromagnetic layer 34. The nonmagnetic layer 36 is provided on the oxide layer 35. The nonmagnetic layer 37 is provided on the nonmagnetic layer 36. The conductive layer 21 is provided above the nonmagnetic layer 37.

The ferromagnetic layer 30 is a ferromagnetic conductor. The ferromagnetic layer 30 has an axis of easy magnetization in a direction perpendicular to the film surface. In the example shown in FIG. 4, a magnetization direction of the ferromagnetic layer 30 is oriented toward the side of the ferromagnetic layer 32. A magnetic field intensity necessary for reversing the magnetization direction of the ferromagnetic layer 30 is, for example, larger than that necessary for reversing the magnetization direction of the ferromagnetic layer 32. A stray field from the ferromagnetic layer 30 reduces an influence of a stray field from the ferromagnetic layer 32 on a magnetization direction of the ferromagnetic layer 34. That is, the ferromagnetic layer 30 functions as a shift canceling layer SCL. The ferromagnetic layer 30 contains, for example, at least one element selected from the group consisting of iron (Fe), cobalt (Co), and nickel (Ni). The ferromagnetic layer 30 may 30 may further contain, as impurities, at least one element selected from the group consisting of boron (B), phosphorus (P), carbon (C), aluminum (Al), silicon (Si), tantalum (Ta), molybdenum (Mo), chromium (Cr), hafnium (Hf), tungsten (W), and titanium (Ti). Specifically, the ferromagnetic layer 30 may contain cobalt iron boron (CoFeB). The ferromagnetic layer 30 may contain at least one binary compound selected from the group consisting of iron boride (FeB), cobalt platinum (CoPt), cobalt nickel (CoNi), and cobalt palladium (CoPd).

The nonmagnetic layer 31 is a nonmagnetic conductor. The nonmagnetic layer 31 is used as a spacer layer SP, and is anti-ferromagnetically coupled to the ferromagnetic layer 30. Thereby, the magnetization direction of the ferromagnetic layer 30 is fixed to a direction anti-parallel to the magnetization direction of the ferromagnetic layer 32. Such a coupling structure of the ferromagnetic layer 30, the nonmagnetic layer 31, and the ferromagnetic layer 32 is referred to as a synthetic anti-ferromagnetic (SAF) structure. The nonmagnetic layer 31 contains, for example, at least one element selected from the group consisting of ruthenium (Ru), osmium (Os), iridium (Ir), vanadium (V), and chromium (Cr).

The ferromagnetic layer 32 is a ferromagnetic conductor. The ferromagnetic layer 32 has an axis of easy magnetization in a direction perpendicular to the film surface. The magnetization direction of the ferromagnetic layer 32 is fixed to the side of the ferromagnetic layer 30 or the side of the ferromagnetic layer 34. In the example shown in FIG. 4, the magnetization direction of the ferromagnetic layer 32 is fixed to the side of the ferromagnetic layer 30. Thus, the ferromagnetic layer 32 is used as a reference layer RL of the MTJ element. The reference layer RL may be referred to as a “pin layer” or a “fixed layer”. The ferromagnetic layer 32 contains, for example, at least one element selected from the group consisting of iron (Fe), cobalt (Co), and nickel (Ni). The ferromagnetic layer 32 may further contain, as impurities, at least one element selected from the group consisting of boron (B), phosphorus (P), carbon (C), aluminum (Al), silicon (Si), tantalum (Ta), molybdenum (Mo), chromium (Cr), hafnium (Hf), tungsten (W), and titanium (Ti). Specifically, the ferromagnetic layer 32 may contain cobalt iron boron (CoFeB). The ferromagnetic layer 32 may contain at least one binary compound selected from the group consisting of iron boride (FeB), cobalt platinum (CoPt), cobalt nickel (CoNi), and cobalt palladium (CoPd).

The nonmagnetic layer 33 is a nonmagnetic insulator. The nonmagnetic layer 33 forms a magnetic tunnel junction together with the ferromagnetic layers 32 and 34. That is, the nonmagnetic layer 33 functions as a tunnel barrier layer TB of the MTJ element. Also, the nonmagnetic layer 33 functions as a seed material during a crystallization process of the ferromagnetic layers 32 and 34, which is included in a manufacturing process of the magnetic memory device 1. The seed material corresponds to a material to be a nucleus for growing a crystalline film from an interface with the ferromagnetic layers 32 and 34. The nonmagnetic layer 33 contains, for example, an oxide of at least one element or compound selected from the group consisting of magnesium (Mg), aluminum (Al), zinc (Zn), titanium (Ti), and lanthanum-strontium-manganese (LSM).

The ferromagnetic layer 34 is a ferromagnetic conductor. The ferromagnetic layer 34 has an axis of easy magnetization in a direction perpendicular to the film surface. A magnetization direction of the ferromagnetic layer 34 is oriented toward either the side of the ferromagnetic layer 32 or the side of the oxide layer 35. The magnetization direction of the ferromagnetic layer 34 is formed to be reversed more easily than that of the ferromagnetic layer 32. Thereby, the ferromagnetic layer 34 is used as a storage layer (SL) of the MTJ element. The storage layer SL may be referred to as a “free layer”. The ferromagnetic layer 34 contains, for example, at least one element selected from the group consisting of iron (Fe), cobalt (Co), and nickel (Ni). The ferromagnetic layer 34 may further contain, as impurities, at least one element selected from the group consisting of boron (B), phosphorus (P), carbon (C), aluminum (Al), silicon (Si), tantalum (Ta), molybdenum (Mo), chromium (Cr), hafnium (Hf), tungsten (W), and titanium (Ti). Specifically, the ferromagnetic layer 34 may contain cobalt iron boron (CoFeB) or iron boride (FeB).

The oxide layer 35 is a nonmagnetic oxide. The oxide layer 35 is used as an SL capping layer SLCP with respect to the ferromagnetic layer 34 (storage layer SL). The oxide layer 35 is in contact with the ferromagnetic layer 34. In other words, the SL capping layer SLCP is in contact with the storage layer SL. The oxide layer 35 is a quaternary oxide containing magnesium (Mg), a rare-earth element, and a noble-metal element. The composition ratio of the noble-metal element contained in the oxide layer 35 may be smaller than that of magnesium (Mg) and the rare-earth element. The rare-earth element contained in the oxide layer 35 includes at least one element selected from the group consisting of scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu). It is more preferable, for example, that one of gadolinium (Gd), yttrium (Y), and scandium (Sc) be selected as the rare-earth element contained in the oxide layer 35. The noble-metal element contained in the oxide layer 35 includes at least one element selected from the group consisting of iridium (Ir), platinum (Pt), and ruthenium (Ru).

The quaternary oxide has a function of improving perpendicular magnetic anisotropy (PMA) of the ferromagnetic layer 34. The quaternary oxide increases an anisotropy field (Hk) of the ferromagnetic layer 34 compared to, for example, a binary oxide containing a rare-earth element or a ternary oxide containing magnesium (Mg) and a rare-earth element.

The nonmagnetic layer 36 is a nonmagnetic conductor. The nonmagnetic layer 36 contains at least one element selected from the group consisting of tungsten (W) and molybdenum (Mo). The nonmagnetic layer 36 is used as a top layer TL. The top layer TL may have, for example, a function of enhancing the characteristics of the MTJ element, a function as a hard mask, and a function as an electrode. Since the nonmagnetic layer 36 contains molybdenum (Mo) or tungsten (W), the anisotropy field of the ferromagnetic layer 34 increases. A comparison will be made between the case where the nonmagnetic layer 36 contains molybdenum (Mo) and the case where the nonmagnetic layer 36 contains tungsten (W) in, for example, a layer structure corresponding to a variable resistance element VR formed on a silicon substrate in a blanket state before being formed into the element by an etching process. In the case where the nonmagnetic layer 36 contains molybdenum (Mo), the anisotropy field of the ferromagnetic layer 34 decreases, but an increase in magnetic coercive force of the ferromagnetic layer 34 can be suppressed, compared to the case where the nonmagnetic layer 36 contains tungsten (W). The material of the nonmagnetic layer 36 may be suitably selected based on the anisotropy field (perpendicular magnetic anisotropy) and the magnetic coercive force of the ferromagnetic layer 34.

The nonmagnetic layer 37 is a nonmagnetic conductor. The nonmagnetic layer 37 is used as a TL capping layer TLCP with respect to the top layer TL. The TL capping layer TLCP may be used as an electrode for improving electrical connectivity between the variable resistance element VR and an upper element (e.g., a switching element SE) or an interconnect (e.g., a bit line BL). The nonmagnetic layer 37 contains, for example, at least one element selected from platinum (Pt), tungsten (W), tantalum (Ta), and ruthenium (Ru).

The above-described variable resistance element VR functions as a perpendicular magnetization-type MTJ element that utilizes the tunneling magnetoresistance (TMR) effect. The variable resistance element VR may be in either a low-resistance state or a high-resistance state according to the relative relationship between the magnetization directions of the ferromagnetic layers 32 and 34. Specifically, the variable resistance element VR is in a high-resistance state if the magnetization directions of the reference layer RL and the storage layer SL are in an anti-parallel state (AP-state), and is in a low-resistance state if the magnetization directions of the reference layer RL and the storage layer SL are in a parallel state (P-state).

The magnetic memory device 1 can store desired data in the memory cell MC by varying the magnetization direction of the ferromagnetic layer 34 (storage layer SL). Specifically, the magnetic memory device 1 controls the magnetization direction of the storage layer SL by letting a write current flow to the variable resistance element VR to inject spin torque into the storage layer SL and the reference layer RL. Such a write method is called a “spin-injection write method”.

In this example, the variable resistance element VR is turned to the AP-state if a write current is allowed to flow in a direction from the ferromagnetic layer 32 toward the ferromagnetic layer 34, and is turned to the P-state if a write current is allowed to flow in a direction from the ferromagnetic layer 34 toward the ferromagnetic layer 32. The variable resistance element VR is configured so that the magnetization direction of the ferromagnetic layer 32 remains unvaried if a current having a magnitude that may cause the magnetization direction of the ferromagnetic layer 34 to be reversed is allowed to flow to the variable resistance element VR. That is, the expression “a magnetization direction is fixed” means that the magnetization direction does not vary in response to an electric current of such a magnitude that the magnetization direction of the ferromagnetic layer 34 may be reversed.

The variable resistance element VR may also include other layers, and each magnetic layer may be formed of a plurality of layers. For example, the ferromagnetic layer 32 may be a layer stack including a plurality of layers. A layer stack that configures the ferromagnetic layer 32 may include, for example, a layer containing cobalt iron boron (CoFeB) or iron boron (FeB) as an interface layer with the nonmagnetic layer 33, while including an additional ferromagnetic layer between that interface layer and the nonmagnetic layer 31 with a nonmagnetic conductor interposed therebetween.

2. Comparison in Characteristics Based on Difference in SL Capping Layer and Top layer

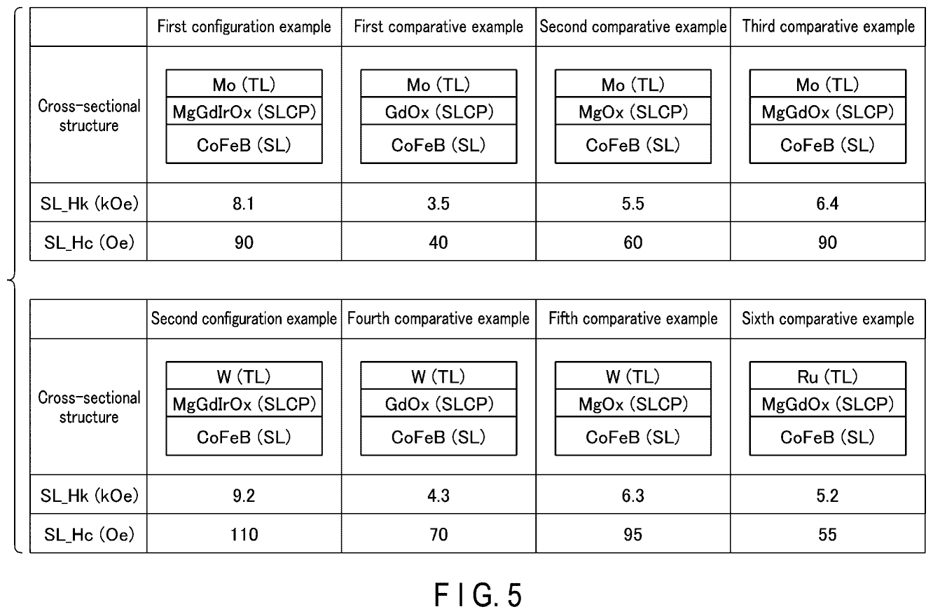

Next, a comparison in characteristics based on a difference in the SL capping layer SLCP and the top layer TL will be described with reference to FIG. 5. FIG. 5 is a schematic diagram showing an example of a change in characteristics based on a difference in the SL capping layer SLCP and the top layer TL. FIG. 5 shows first and second configuration examples according to the present embodiment, and first to six comparative examples. In the cross-sectional structure of each example, the ferromagnetic layer 34 (storage layer SL), the oxide layer 35 (SL capping layer SLCP), and the nonmagnetic layer 36 (top layer TL) of the layer structure corresponding to the variable resistance element VR formed on a silicon substrate are extracted. In the first and second configuration examples and the first to sixth comparative examples, each layer has substantially the same thickness and size. The anisotropy field SL_Hk and the magnetic coercive force SL_Hc of the storage layer SL in each example of FIG. 5 show results obtained by measuring characteristics of a layer structure corresponding to a variable resistance element VR formed on a silicon substrate in a blanket state before being formed into the element by an etching process.

For example, the magnetic coercive force SL_Hc of the storage layer SL in the blanket state increases due to structural disturbance in the storage layer SL. It is thus preferable that the magnetic coercive force SL_Hc of the storage layer SL in the blanket state be as small as possible. On the other hand, the magnetic coercive force SL_Hc of the storage layer SL that has been processed to form a variable resistance element VR is correlated to thermal stability. It is thus preferable that the magnetic coercive force SL_Hc of the storage layer SL in the element state be as large as possible.

As shown in FIG. 5, cobalt iron boron (CoFeB) is commonly used as the storage layer SL in the first and second configuration examples and the first to sixth comparative examples. In the first and second configuration examples and the first to sixth comparative examples, different materials are used as the SL capping layer SLCP and the top layer TL.

The first and second configuration examples are identical in the material of the SL capping layer SLCP, but differ in the material of the top layer TL. More specifically, a magnesium gadolinium iridium oxide (MgGdIrOx) containing, as an example of the quaternary oxide, magnesium (Mg), gadolinium (Gd) as the rare-earth element, and iridium(Ir) as the noble-metal element is used as the SL capping layer SLCP of the first and second configuration examples. Molybdenum (Mo) is used as the top layer TL of the first configuration example. On the other hand, tungsten (W) is used as the top layer TL of the second configuration example.

The first and fourth comparative examples are identical in the material of the SL capping layer SLCP, but differ in the material of the top layer TL. More specifically, a gadolinium oxide (GdOx) containing gadolinium (Gd) as the rare-earth element is used as an example of the binary oxide containing a rare-earth element for the SL capping layer SLCP in the first and fourth comparative examples. Molybdenum (Mo) is used as the top layer TL of the first comparative example. On the other hand, tungsten (W) is used as the top layer TL of the fourth comparative example.

The second and fifth comparative examples are identical in the material of the SL capping layer SLCP, but differ in the material of the top layer TL. More specifically, a magnesium oxide (MgOx) containing magnesium (Mg) is used as an example of the binary oxide for the SL capping layer SLCP in the second and fifth comparative examples. Molybdenum (Mo) is used as the top layer TL of the second comparative example. On the other hand, tungsten (W) is used as the top layer TL of the fifth comparative example.

The third and sixth comparative examples are identical in the material of the SL capping layer SLCP, but differ in the material of the top layer TL. More specifically, magnesium gadolinium oxide (MgGdOx) containing magnesium (Mg) and gadolinium(Gd) as a rare-earth element is used as an example of a ternary oxide for the SL capping layer SLCP in the third and sixth comparative examples. Molybdenum (Mo) is used as the top layer TL of the third comparative example. On the other hand, ruthenium (Ru) is used as the top layer TL of the fifth comparative example.

The storage layer SL in the first configuration example has an anisotropy field SL_Hk of 8.1 kOe. The storage layer SL has a magnetic coercive force SL_Hc of 90 Oe.

The storage layer SL in the second configuration example has an anisotropy field SL_Hk of 9.2 kOe. The storage layer SL has a magnetic coercive force SL_Hc of 110 Oe.

The storage layer SL in the first comparative example has an anisotropy field SL_Hk of 3.5 kOe. The storage layer SL has a magnetic coercive force SL_Hc of 40 Oe.

The storage layer SL in the second comparative example has an anisotropy field SL_Hk of 5.5 kOe. The storage layer SL has a magnetic coercive force SL_Hc of 60 Oe.

The storage layer SL in the third comparative example has an anisotropy field SL_Hk of 6.4 kOe. The storage layer SL has a magnetic coercive force SL_Hc of 90 Oe.

The storage layer SL in the fourth comparative example has an anisotropy field SL_Hk of 4.3 kOe. The storage layer SL has a magnetic coercive force SL_Hc of 70 Oe.

The storage layer SL in the fifth comparative example has an anisotropy field SL_Hk of 6.3 kOe. The storage layer SL has a magnetic coercive force SL_Hc of 95 Oe.

The storage layer SL in the sixth comparative example has an anisotropy field SL_Hk of 5.2 kOe. The storage layer SL has a magnetic coercive force SL_Hc of 55 Oe.

First, differences in the SL capping layer SLCP will be focused on. A comparison will be made between, for example, a first configuration example, a first comparative example, a second comparative example, and a third comparative example in which molybdenum (Mo) is used as the top layer TL and different materials are used as the SL capping layer SLCP. That is, the first configuration example in which MgGdIrOx is used as the SL capping layer SLCP, the first comparative example in which GdOx is used as the SL capping layer SLCP, the second comparative example in which MgOx is used as the SL capping layer SLCP, and the third comparative example in which MgGdOx is used as the SL capping layer SLCP will be compared. A comparison between the magnitudes of the anisotropy fields SL_Hk of the storage layers SL of these structures shows that the following relationship is satisfied: first configuration example(MdGdIrOx)>third comparative example(MgGdOx)>second comparative example(MgOx)>first comparative example(GdOx). That is, the anisotropy field SL_Hk of the storage layer SL becomes greatest in the case where MgGdIrOx is used as the SL capping layer. In other words, the anisotropy field SL_Hk of the storage layer SL becomes great in the case where the quaternary oxide of the present embodiment is used as the SL capping layer SLCP, compared to the binary oxide and the ternary oxide. If, for example, Ir is added to MgGdOx of the third comparative example, the anisotropy field SL_Hk of the storage layer SL increases, as shown in the first configuration example. A similar result is obtained in the case where a comparison is made between the second configuration example, the fourth comparative example, and the fifth comparative example in which tungsten (W) is used as the top layer TL and different materials are used as the SL capping layer SLCP.

In general, if film characteristics in the blanket state are measured, the magnetic coercive force SL_Hc of the storage layer SL increases as the anisotropy field SL_Hk of the storage layer SL increases. However, if a comparison is made between the first configuration example and the third comparative example in the blanket state, the storage layer SL of the first configuration example has an anisotropy field SL_Hk greater than that of the third comparative example, but the storage layers SL of the first and third comparative examples have the same magnetic coercive force SL_Hc. Accordingly, MgGdIrOx used as the SL capping layer SLCP has a function of increasing an anisotropy field SL_Hk of the storage layer SL, namely, the perpendicular magnetic anisotropy, while minimizing an increase in the magnetic coercive force SL_Hc of the storage layer SL based on the blanket-state film characteristics.

Next, differences in the top layer TL will be focused on. First, a comparison will be made between third and sixth comparative examples in which different materials are used as the top layer TL and the same material is used as the SL capping layer SLCP. That is, the third comparative example in which molybdenum (Mo) is used as the top layer TL and the sixth comparative example in which ruthenium (Ru) is used as the top layer TL will be compared. A comparison between the magnitudes of the anisotropy fields SL_Hk of the storage layers SL of these structures shows that the following relationship is satisfied: third comparative example>sixth comparative example. That is, the anisotropy field SL_Hk of the storage layer SL becomes greater in the case where molybdenum (Mo) is used as the top layer TL than in the case where ruthenium (Ru) is used as the top layer TL.

Also, a comparison will be made between, for example, the first and second configuration examples in which different materials are used as the top layer TL and the same material is used as the SL capping layer SLCP. That is, the first configuration example in which molybdenum (Mo) is used as the top layer TL and the second configuration example in which tungsten (W) is used as the top layer TL will be compared. A comparison between the magnitudes of the anisotropy fields SL_Hk of the storage layers SL of these structures shows that the following relationship is satisfied: second configuration example>first configuration example. That is, the anisotropy field SL_Hk of the storage layer SL becomes greater in the case where tungsten (W) is used as the top layer TL than in the case where molybdenum (Mo) is used as the top layer TL. Also, a comparison between the magnitudes of the magnetic coercive forces SL_Hc of the storage layers SL of these structures in the blanket state shows that the following relationship is satisfied: second configuration example>first configuration example. That is, it can be seen, based on a comparison between the blanket-state film characteristics, that the anisotropy field SL_Hk of the storage layer SL and the magnetic coercive force SL_Hc of the storage layer SL become greater in the case where tungsten (W) is used as the top layer TL than in the case where molybdenum (Mo) is used as the top layer TL. Similar results are obtained in the case where a comparison is made between the first and fourth comparative examples and in the case where the second and fifth comparative examples are compared.

It can be seen, based on a comparison between the blanket-state film characteristics, that molybdenum (Mo) and tungsten (W) used as the top layer TL have the function of increasing the anisotropy field SL_Hk of the storage layer SL, namely, the perpendicular magnetic anisotropy. In addition, molybdenum (Mo) used as the top layer TL has a small effect in an increase of the anisotropy field SL_Hk of the storage layer SL, compared to tungsten (W), but suppresses an increase in the magnetic coercive force SL_Hc of the storage layer SL.

### 3. Advantageous Effects of Embodiment

With the magnetic memory device 1 according to the embodiment described above, it is possible to improve the characteristics of the memory cells MC, while suppressing failure occurrences. Hereinafter, details of the effects of the magnetic memory device 1 according to the embodiment will be described.

As a method of increasing the storage capacity of the magnetic memory device, arranging the memory cells MC in a high density is conceivable. With the memory cells MC being miniaturized and arranged in a smaller pitch, an improvement in the perpendicular magnetic anisotropy of the storage layer SL is demanded. As a method of improving the anisotropy field SL_Hk of the storage layer SL, there is a method of decreasing the thickness of the storage layer SL. However, with a decrease in the thickness of the storage layer SL, the storage layer SL is highly likely to agglomerate, namely, the surface roughness of the storage layer SL is highly likely to increase. For example, agglomeration of crystalline grains of the storage layer SL causes a disturbance in the interface between the storage layer SL and the SL capping layer SLCP, resulting in an increase in the surface roughness. The agglomeration (an increase in the surface roughness) of the storage layer SL increases variations in the resistance value and the magnetic coercive force of the MTJ element (variable resistance element VR). This deteriorates the characteristics of the memory cells MC, increasing the possibility of failure occurrences.

On the other hand, with the configuration of the present embodiment, a quaternary oxide containing, as the SL capping layer SLCP of the storage layer SL, magnesium (Mg), a rare-earth element, and a noble-metal element can be used. Also, as the top layer TL, a nonmagnetic layer containing tungsten (W) or molybdenum (Mo) can be used. It is thereby possible to improve the anisotropy field SL_Hk of the storage layer SL. That is, it is possible to improve the perpendicular magnetic anisotropy of the storage layer SL. Accordingly, it is possible to improve the characteristics of the memory cells MC, while suppressing failure occurrences.

Moreover, with the configuration according to the present embodiment, since the storage layer SL and the quaternary oxide used as the SL capping layer SLCP are in contact with each other, the anisotropy field Hk caused by the interface of the storage layer SL increases. This improves the characteristics of the memory cells MC.

### 4. Others

In the embodiment, the magnetic memory device 1 has been described as an example of a magnetic device including an MTJ element (variable resistance element VR), but the embodiment is not limited thereto. The magnetic device may be other devices that require a magnetic element having perpendicular magnetic anisotropy such as a sensor or a medium. It suffices that that the magnetic element uses at least a variable resistance element VR.

In the present specification, the term “couple” refers to electrical coupling, and does not exclude interposition of another component. Each of the nonmagnetic layers 31, 36, and 37 may be referred to as a “conductive layer”. The nonmagnetic layer 33 may be referred to as an “oxide layer”. The oxide layer 35 may be referred to as a “nonmagnetic layer”. The elements contained in each layer of the MTJ element can be measured by, for example, using electron energy loss spectroscopy (EELS) with a scanning transmission electron microscope (STEM).

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory device, comprising:
a first ferromagnetic layer;
a first nonmagnetic layer provided on the first ferromagnetic layer;
a second ferromagnetic layer provided on the first nonmagnetic layer;
an oxide layer containing magnesium (Mg), a rare-earth element, and a noble-metal element and provided on the second ferromagnetic layer; and
a second nonmagnetic layer provided on the oxide layer.

2. The magnetic memory device according to claim 1, wherein
the rare-earth element includes at least one element selected from the group consisting of scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu).

3. The magnetic memory device according to claim 1, wherein
the noble-metal element includes at least one element selected from the group consisting of iridium (Ir), platinum (Pt), and ruthenium (Ru).

4. The magnetic memory device according to claim 1, wherein
the second nonmagnetic layer includes an element that is either tungsten (W) or molybdenum (Mo).

5. The magnetic memory device according to claim 1, wherein
the second ferromagnetic layer and the oxide layer are in contact with each other.

6. The magnetic memory device according to claim 1, wherein
the first ferromagnetic layer contains at least one element selected from the group consisting of iron (Fe), cobalt (Co), and nickel (Ni),
the first nonmagnetic layer includes an oxide of at least one element or compound selected from the group consisting of magnesium (Mg), aluminum (Al), zinc (Zn), titanium (Ti), and lanthanum-strontium-manganese (LSM), and
the second ferromagnetic layer contains at least one element selected from the group consisting of iron (Fe), cobalt (Co), and nickel (Ni).

7. The magnetic memory device according to claim 1, further comprising:
a third ferromagnetic layer provided below the first ferromagnetic layer; and
a third nonmagnetic layer provided between the first ferromagnetic layer and the third ferromagnetic layer.

8. The magnetic memory device according to claim 7, wherein
the third nonmagnetic layer is anti-ferromagnetically coupled to the third ferromagnetic layer, and
a magnetization direction of the third ferromagnetic layer is fixed to a direction anti-parallel to a magnetization direction of the first ferromagnetic layer.

9. The magnetic memory device according to claim 7, wherein
a stray field from the third ferromagnetic layer reduces an influence of a stray field from the first ferromagnetic layer on a magnetization direction of the second ferromagnetic layer.

10. The magnetic memory device according to claim 7, wherein
the third ferromagnetic layer contains at least one element selected from the group consisting of iron (Fe), cobalt (Co), and nickel (Ni).

11. The magnetic memory device according to claim 7, wherein
the third nonmagnetic layer contains at least one element selected from the group consisting of ruthenium (Ru), osmium (Os), iridium (Ir), vanadium (V), and chromium (Cr).

12. The magnetic memory device according to claim 1, wherein
each of the first ferromagnetic layer and the second ferromagnetic layer has an axis of easy magnetization in a direction perpendicular to a film surface,
a magnetization direction of the first ferromagnetic layer is fixed, and
a magnetization direction of the second ferromagnetic layer is configured to be reversed more easily than the magnetization direction of the first ferromagnetic layer.

13. The magnetic memory device according to claim 1, further comprising:
a fourth nonmagnetic layer provided on the second nonmagnetic layer, wherein
the fourth nonmagnetic layer contains at least one element selected from platinum (Pt), tungsten (W), tantalum (Ta), and ruthenium (Ru).

14. The magnetic memory device according to claim 1, further comprising:
a first conductive layer extending in a first direction;
a second conductive layer extending in a second direction intersecting the first direction and provided apart from the first conductive layer; and
a memory cell provided between the first conductive layer and the second conductive layer, wherein
the memory cell includes the first ferromagnetic layer, the first nonmagnetic layer, the second ferromagnetic layer, the oxide layer, and the second nonmagnetic layer.

15. The magnetic memory device according to claim 2, wherein
the noble-metal element includes at least one element selected from the group consisting of iridium (Ir), platinum (Pt), and ruthenium (Ru).

16. The magnetic memory device according to claim 14, wherein
the memory cell further includes a variable resistance element and a switching element coupled in series to the variable resistance element, and
the variable resistance element includes the first ferromagnetic layer, the first nonmagnetic layer, the second ferromagnetic layer, the oxide layer, and the second nonmagnetic layer.

17. The magnetic memory device according to claim 16, wherein
the variable resistance element is electrically coupled, at one end, to the second conductive layer, and coupled, at another end, to the switching element.

18. The magnetic memory device according to claim 17, wherein
the switching element is turned on when a voltage higher than a threshold voltage of the switching element is applied to the switching element.
